(19) United States
(12) Patent Application Publication
(10) Pub. No.: US 2023/0187418 A1
(43) Pub. Date: Jun. 15, 2023

(54) FULL-COLOR LED DISPLAY USING MICRO-NANOPIN LED ELEMENTS, AND METHOD FOR PRODUCING SAME

(71) Applicant: KOOKMIN UNIVERSITY INDUSTRY ACADEMY COOPERATION FOUNDATION, Seoul (KR)

(72) Inventor: Young Rag DO, Delaware, OH (US)

(73) Assignee: KOOKMIN UNIVERSITY INDUSTRY ACADEMY COOPERATION FOUNDATION, Seoul (KR)

(21) Appl. No.: 17/997,255

(22) PCT Filed: Apr. 27, 2021
(86) PCT No.: PCT/KR2021/005310

§ 371 Date: Oct. 27, 2022

(30) Foreign Application Priority Data
Apr. 27, 2020 (KR) 10-2020-0050885

(51) Int. Cl. H01L 25/075; H01L 33/20; H01L 33/38; H01L 33/00; H01L 33/62; H01L 33/50

(52) U.S. Cl. CPC H01L 25/0753; H01L 33/005; H01L 33/20; H01L 33/62; H01L 33/382; H01L 33/505; H01L 2933/0016; H01L 2933/0041; H01L 2933/0066

(57) ABSTRACT

The present invention relates to a full-color LED display, more particularly, to a full-color LED display using micro-nanofin LED elements and manufacturing method thereof.

### TECHNICAL FIELD

The present invention relates to a full-color LED display, and more particularly, to a full-color LED display using micro-nanofin LED elements and a method for manufacturing the same.

### DESCRIPTION OF RELATED ART

Micro-LEDs and nano-LEDs may implement an excellent feeling of color and high efficiency and may be eco-friendly materials and long-life and self-emission elements, so they are used as core materials for displays. Research and development are continuing to apply micro-LED displays or nano-LED displays to various displays such as smartphones and TVs. In addition, recently, research on a new structure or a new patterning manufacturing process has been actively conducted to commercialize micro-LED or nano-LED displays.

Recently, large-sized displays for TVs of 100 inches or more using red, green, and blue micro-LEDs have been commercialized, and in the future, TVs, which implement full-color through blue subpixels implemented using blue micro-LEDs or nano-LEDs and red and green subpixels implemented using quantum dots emission through the blue LEDs, will be commercialized. In addition, red, green, and blue nano-LED display TVs will also be commercialized.

Micro-LED displays have advantages such as high performance characteristics, very long theoretical lifetime, and very high efficiency, but when micro-LED displays are developed as displays with 8 K resolution, a red micro-LED, a green micro-LED, and a blue micro-LED should be put in one-to-one correspondence with each of nearly 100 million subpixels. Thus, through pick and place technology for manufacturing micro-LED displays, it is difficult to manufacture true high-resolution commercial displays ranging from smartphones to TVs due to the limitations of process technology, considering a high unit price, a high process defect rate, and low productivity. In addition, it is more difficult to individually arrange nano-LEDs on subpixels using pick and place technology for micro-LEDs.

In order to overcome such difficulty, Korean Patent Registration No. 10-1436123 discloses a display manufactured through a method of dropfing a solution mixed with nanorod-type LEDs on subpixels and then forming an electric field between two alignment electrodes to self-align nanorod-type LED elements on the electrodes and form the subpixels. However, in the disclosed display, the electrodes for applying a current to a p-type semiconductor layer and n-type semiconductor layer of the nanorod-type LED element are spaced apart in the horizontal direction, so there is a problem in that it is not easy to arrange horizontal and vertical electrodes for addressing in preparing subpixels. In addition, there are problems in that a large number of LEDs must be mounted in order to express desired efficiency because the efficiency is not good due to the small area from which light is extracted, and there is the high possibility of unavoidable defects in the manufacturing process of the nanorod-type LED itself.

The unavoidable defect of the nanorod itself will be described in detail. A method is known in which a nanopatteming process in combination with dry etching/wet etching are performed on an LED wafer to manufacture nanorod-type LED elements in a top-down manner, or nanorod-type LED elements are grown directly on a substrate in a bottom-up manner. In such nanorod-type LEDs, since a major axis of an LED coincides with a stack direction, that is, a stack direction of each layer in a p-GaN/InGaN multi-quantum well (MQW)/n-GaN stacked structure, an emission area is narrow. Since the emission area is narrow, surface defects have a relatively large effect on a degradation in efficiency, and it is difficult to optimize an electron-hole recombination rate, which may cause a problem in that luminous efficiency is significantly lower than that of an original wafer.

Therefore, there is an urgent need to develop a display based on a new LED material that easily implements an electrode arrangement for addressing when manufacturing subpixels, easily arranges micro- and nano-scale elements using an electric field, as well as having a wide emission area, minimizing or preventing a degradation in efficiency due to surface defects, and having an optimized electron-hole recombination rate.

### SUMMARY

The present invention has been devised to solve the above problems, and an object of the present invention is to provide a full-color LED display using a micro-nanofin LED element having high luminance and maintaining high efficiency by increasing an emission area and a method for manufacturing the same.

In addition, another object of the present invention is to provide a full-color LED display using a micro-nanofin LED element that can minimize a degradation in electron-hole recombination efficiency due to non-uniformity of electron and hole velocities and a resulting degradation in luminous efficiency, and greatly reduces an area of a photoactive layer exposed to a surface while increasing an emission area, thereby preventing a degradation in efficiency due to surface defects, and a method for manufacturing the same.

Furthermore, another object of the present invention is to provide a full-color LED display using a micro-nanofin LED element improved to be suitable for a method of self-aligning an element on an electrode by an electric field, and a method for manufacturing the same.

In addition, another object of the present invention is to provide a full-color LED display capable of more easily designing and implementing an electrode arrangement for addressing when implementing subpixels of the display and a manufacturing method thereof.

In order to achieve the above objects, a first embodiment of the present invention provides a method for manufacturing a full-color LED display including the steps of (1) self-aligning to include at least two micro-nanopin LED elements which emit substantially the same color of light for each of a plurality of sub-pixel sites formed on a lower electrode line including a plurality of electrodes which are spaced apart in a horizontal direction at a predetermined interval, and have an element length greater than a thickness, wherein a first conductive semiconductor layer, a photoactive layer and a second conductive semiconductor layer are stacked in a thickness direction, (2) forming an upper electrode line so as to be in contact with upper portions of the self-aligned micro-nanofin LED elements, and (3) patterning a color conversion layer on the upper electrode line so that each of the plurality of subpixel sites becomes the subpixel site expressing any one color among blue, green, and red.

According to an embodiment of the present invention, the step (1) may be performed by including the steps of 1-1) preparing the lower electrode line including the plurality of electrodes spaced apart in the horizontal direction at the predetermined interval, 1-2) injecting a solution including a plurality of the micro-nanofin LED elements which emits substantially the same color of light and has the length greater than the thickness, and in which the first conductive semiconductor layer, the photoactive layer, and the second conductive semiconductor layer are stacked in the thickness direction into the plurality of subpixel sites formed on the lower electrode line; and 1-3) self-aligning the plurality of micro-nanofin LED elements by applying an assembly voltage to the lower electrode line so that the at least two micro-nanofin LED elements contact the different electrodes positioned in each of the subpixel sites on the lower electrode line.

In addition, the light color may be blue, white or UV.

In addition, the micro-nanofin LED element may be a rod-type element that has a plane having a length and width of nano or micro size, and in which a thickness perpendicular to the plane is smaller than the length.

In addition, on the second conductive semiconductor layer of the micro-nanofin LED element, an electrode layer or a polarization inducing layer may be further included. The polarization inducing layer includes a first polarization inducing layer formed on one end in the longitudinal direction of the element, and a second polarization inducing layer having an electrical polarity different from that of the first polarization inducing layer on the other end in the longitudinal direction of the element.

In addition, the distance between the plurality of electrodes may be smaller than the length of the micro-nanofin LED element.

In addition, between the steps of self-aligning the micro-nanofin LED elements and forming the upper electrode line, the steps of forming a conductive metal layer connecting any one layer of each of the micro-nanofin LED elements in contact with the lower electrode line and the lower electrode line, and forming an insulating layer on the lower electrode line to a thickness that does not cover the upper surfaces of the self-aligned micro-nanofin LED elements may be further included.

In addition, a ratio of the length and thickness of the micro-nanofin LED element may be 3: 1 or more.

In addition, a protrusion having a predetermined width and thickness may be formed on a lower surface of the first conductive semiconductor layer of the micro-nanofin LED element in the longitudinal direction of the element.

In addition, a first embodiment of the present invention provides a full-color LED display, including a lower electrode line that includes a plurality of electrodes spaced apart in a horizontal direction at a predetermined interval, a plurality of micro-nanofin LED elements that has a length greater than a thickness, in which a first conductive semiconductor layer, a photoactive layer, and a second conductive semiconductor layer are stacked in a thickness direction, and emit substantially the same color of light, in which at least two of the plurality of micro-nanofin LED elements are included for each of a plurality of subpixel sites formed on the lower electrode line, and the included elements emit substantially the same color of light, an upper electrode line disposed to contact upper portions of the plurality of micro-nanofin LED elements, and a color conversion layer patterned on the upper electrode line so that each of the plurality of subpixel sites becomes the subpixel site expressing any one color among blue, green, and red.

According to an embodiment of the present invention, the micro-nanofin LED element may have the length of 1000 to 10000 nm and the thickness of 100 to 3000 nm.

In addition, a width of the micro-nanofin LED element may be greater than or equal to the thickness.

In addition, an emission area of the micro-nanofin LED element may exceed twice an area of a vertical cross-section of the micro-nanofin LED element.

In addition, any one of the first conductive semiconductor layer and the second conductive semiconductor layer may include a p-type GaN semiconductor layer, the other may include an n-type GaN semiconductor layer, and the p-type GaN semiconductor layer may have a thickness of 10 to 350 nm, the n-type GaN semiconductor layer may have a thickness of 100 to 3000 nm, and the photoactive layer may have a thickness of 30 to 200 nm.

In addition, the element may further include a protective film formed on a side surface of the element to cover an exposed surface of the photoactive layer.

In addition, a lower surface of the first conductive semiconductor layer of the micro-nanofin LED element may have a protrusion having a predetermined width and thickness formed in a longitudinal direction of the element. In addition, a width of the protrusion may be formed to have a length of 30% or less compared to the width of the micro-nanofin LED element.

In addition, since the subpixel site may have a unit area of 30 µm×30 µm or less, high resolution is possible.

In addition, a second embodiment of the present invention provides a method for preparing a full-color LED display, including the steps of (a) self-aligning to include at least two micro-nanofin LED elements which emit substantially the same color of light for each of a plurality of sub-pixel sites formed on a lower electrode line including a plurality of electrodes which are spaced apart in a horizontal direction at a predetermined interval, wherein the micro-nanofin LED elements include a blue micro-nanofin LED element, a green micro-nanofin LED element so that each of the plurality of subpixel sites becomes the subpixel site expressing any one color among blue, green and red, and have an element length greater than a thickness, wherein a first conductive semiconductor layer, a photoactive layer and a second conductive semiconductor layer are stacked in a thickness direction; and (b) forming an upper electrode line in contact with upper portions of the self-aligned micro-nanofin LED elements.

According to an embodiment of the present invention, step (a) may include the steps of a-1) preparing the lower electrode line including the plurality of electrodes spaced apart in the horizontal direction at the predetermined interval; a-2) injecting a solution including each of the plurality of the blue micro-nanofin LED elements, the green micro-nanofin LED elements, and the red micro-nanofin LED elements into the plurality of subpixel sites formed on the lower electrode line, wherein the micro-nanofin LED elements have an element length greater than a thickness, wherein a first conductive semiconductor layer, a photoactive layer and a second conductive semiconductor layer are stacked in a thickness direction; and a-3) self-aligning the plurality of micro-nanofin LED elements by applying an assembly voltage to the lower electrode line so that the at least two micro-nanofin LED elements emitting substantially the same color of light contact the different electrodes positioned in each of the subpixel sites on the lower electrode line.

In addition, the micro-nanofin LED element may be a rod-type element that has a plane having a length and width of nano or micro size, and in which a thickness perpendicular to the plane is smaller than the length.

In addition, on the second conductive semiconductor layer of the micro-nanofin LED element, an electrode layer or a polarization inducing layer may be further included. The polarization inducing layer includes a first polarization inducing layer formed on one end in the longitudinal direction of the element, and a second polarization inducing layer having an electrical polarity different from that of the first polarization inducing layer on the other end in the longitudinal direction of the element.

In addition, the distance between the plurality of electrodes may be smaller than the length of the micro-nanofin LED element.

In addition, between the steps of self-aligning the micro-nanofin LED elements and forming the upper electrode line, the steps of forming a conductive metal layer connecting the semiconductor layer of each of the micro-nanofin LED elements in contact with the lower electrode line and the lower electrode line, and forming an insulating layer on the lower electrode line to a thickness that does not cover the upper surfaces of the self-aligned micro-nanofin LED elements may be further included.

In addition, a ratio of the length and thickness of the micro-nanofin LED element may be 3: 1 or more.

In addition, a protrusion having a predetermined width and thickness may be formed on a lower surface of the first conductive semiconductor layer of the micro-nanofin LED element in the longitudinal direction of the element.

In addition, a second embodiment of the present invention provides a full-color LED display, including a lower electrode line that includes a plurality of electrodes spaced apart in a horizontal direction at a predetermined interval, a plurality of micro-nanofin LED elements that emits blue, green, or red light independently of each other, has a length greater than a thickness, in which a first conductive semiconductor layer, a photoactive layer, and a second conductive semiconductor layer are stacked in a thickness direction, and in which at least two of the plurality of micro-nanofin LED elements emitting substantially the same color of light for each of a plurality of subpixel sites are disposed so that the plurality of subpixel sites formed on the lower electrode line independently represents any one color of blue, green, and red, and an upper electrode line disposed to contact upper portions of the plurality of micro-nanofin LED elements.

According to an embodiment of the present invention, the micro-nanofin LED element may have the length of 1000 to 10000 nm and the thickness of 100 to 3000 nm.

In addition, a width of the micro-nanofin LED element may be greater than or equal to the thickness.

In addition, an emission area of the micro-nanofin LED element may exceed twice an area of a vertical cross-section of the micro-nanofin LED element.

In addition, any one of the first conductive semiconductor layer and the second conductive semiconductor layer may include a p-type GaN semiconductor layer, the other may include an n-type GaN semiconductor layer, and the p-type GaN semiconductor layer may have a thickness of 10 to 350 nm, the n-type GaN semiconductor layer may have a thickness of 100 to 3000 nm, and the photoactive layer may have a thickness of 30 to 200 nm.

In addition, the element may further include a protective film formed on a side surface of the element to cover an exposed surface of the photoactive layer.

In addition, a lower surface of the first conductive semiconductor layer of the micro-nanofin LED element may have a protrusion having a predetermined width and thickness formed in a longitudinal direction of the element. In addition, a width of the protrusion may be formed to have a length of 50% or less compared to the width of the micro-nanofin LED element.

In addition, since the subpixel site may have a unit area of 100 µm×100 µm or less, high resolution is possible.

Hereinafter, the terms used in the present invention will be defined.

In descriptions of embodiments of the present invention, it should be understood that when a layer, region, pattern, or structure is referred to as being formed “on,” “upper”, “above,” “under,” “lower”, “below” a substrate, another layer, another region, or another pattern, the terminology of “on,” “upper”, “above,” “under,” “lower”, “below” includes both the meanings of “directly” and “indirectly”.

In description of embodiments of the present invention, the meaning of “contact” includes all cases in which the components 1 and 2 are directly structurally connected or indirectly structurally connected including the configuration 3. For example, the meaning of “a first conductive semiconductor layer in contact with a lower electrode line” is not only when the first conductive semiconductor layer is directly connected to the lower electrode line, but also when an electrode layer is formed on the first conductive semiconductor layer and the first conductive semiconductor layer is indirectly connected to the lower electrode line as the electrode layer and the lower electrode line are directly connected. In addition, in description of embodiments of the present invention, “electrical connection” means a light-emitting state in which a micro-nanofin LED element can emit light when driving power is applied to an electrode line.

A full-color LED display according to the present invention is based on a micro-nanofin LED element that achieves high luminance and light efficiency by increasing an emission area compared to the conventional rod-type LED element, so the LED display has excellent luminance and luminous efficiency. In addition, while increasing the emission area of the used LED element, the area of the photoactive layer exposed on the surface is greatly reduced, thereby preventing or minimizing a degradation in efficiency due to surface defects and a resulting degradation in display luminance. Furthermore, in the LED element used, a degradation in electron-hole recombination efficiency due to non-uniformity of electron and hole velocities and a resulting degradation in luminous efficiency are minimized, and it is very suitable for a method of self-aligning the elements on an electrode by an electric field, so that a display may be implemented more easily. In addition, an electrode array that implements subpixels can be designed easily and simply, and at the same time, there is no difficulty in implementing the electrode array, so the LED element can be widely applied to various displays.

### BRIEF DESCRIPTION OF THE DRAWINGS

FIGS. 1 to 2 are a schematic plan view of a full-color LED display according to a first embodiment of the present invention and a schematic cross-sectional view along the boundary line X-X′ of FIG. 1,

FIGS. 3 to 4 are a schematic plan view of a full-color LED display according to a second embodiment of the present invention and a schematic cross-sectional view along the boundary line Y-Y′ of FIG. 3,

FIGS. 5A and 5B are a schematic view of a micro-nanofin LED element included in an embodiment of the present invention in which a first conductive semiconductor layer, a photoactive layer, and a second conductive semiconductor layer are stacked in a thickness direction, respectively, and a schematic view of a horizontally arranged rod-type element in which a first conductive semiconductor layer, a photoactive layer, and a second conductive semiconductor layer are stacked in a longitudinal direction,

FIGS. 6 to 8 are a perspective view of a micro-nanofin LED element included in an embodiment of the present invention, a cross-sectional view along the boundary line X-X′, and a cross-sectional view along the boundary line Y-Y′,

FIG. 9 is a schematic view of a manufacturing process of a micro-nanofin LED element according to FIG. 6,

FIGS. 10 to 12 are a perspective view of another micro-nanofin LED element included in an embodiment of the present invention, a cross-sectional view taken along the boundary line X-X′, and a cross-sectional view taken along the boundary line Y-Y′,

FIG. 13 is a schematic view of a manufacturing process of the micro-nanofin LED element according to FIG. 10, and

FIG. 14 is a cross-sectional schematic view of a contact aspect between a lower electrode line and a micro-nanofin LED element included in an embodiment of the present invention.

### DETAILED DESCRIPTION OF THE INVENTION

Hereinafter, embodiments of the present invention will be described in detail with reference to the accompanying drawings such that those skilled in the art to which the present invention can easily carry out the present invention. It should be understood that the present invention may be embodied in various different forms and is not limited to the following embodiments. In addition, in the case of a general description of a display to be described later, the contents of Korean Patent Application Nos. 10-2011-0040925 and 10-2013-0080412 by the inventor of the present invention are incorporated herein by reference.

First, a full-color LED display implemented with LED elements emitting substantially the same color of light as a display according to the first embodiment of the present invention will be described.

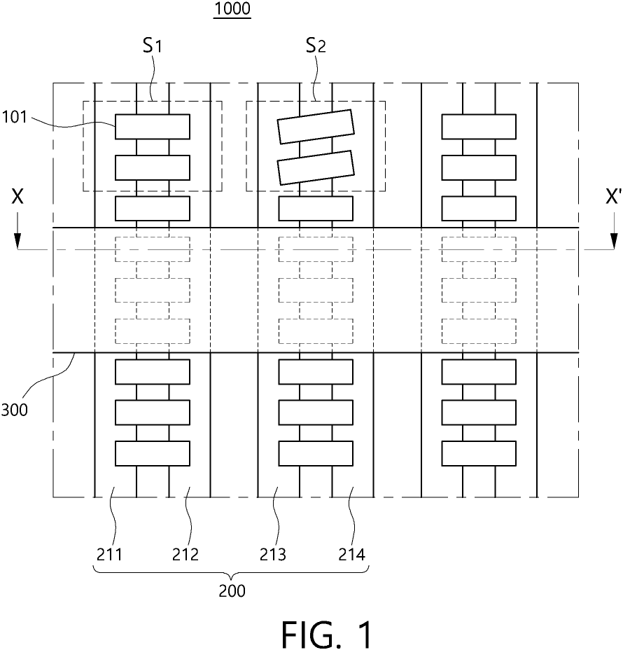

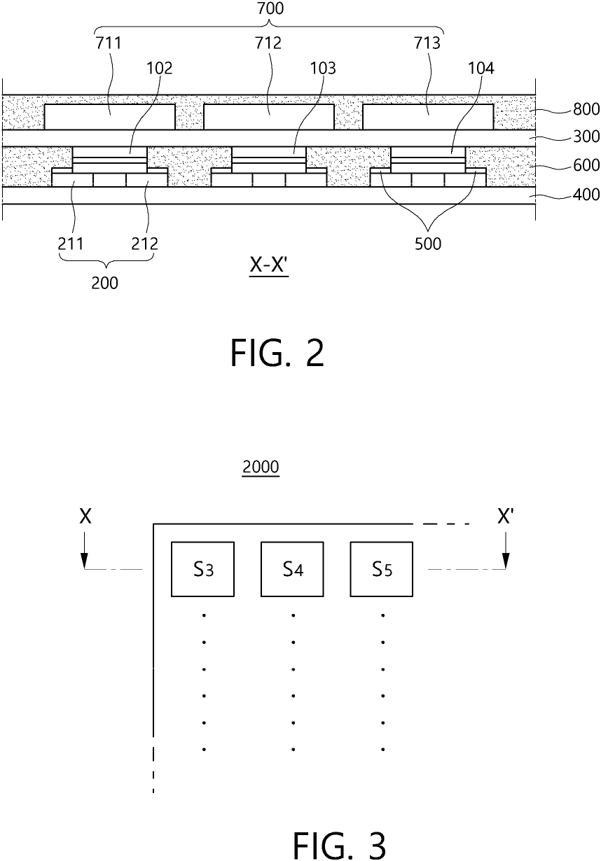

When described with reference to FIGS. 1 and 2, a full-color LED display 1000 according to a first embodiment of the present invention is implemented by including a lower electrode 200 including a plurality of electrodes 211, 212, 213, 214 that is horizontally spaced apart at a predetermined interval, micro-nanofin LED elements 101, 102, 103, 104 in which entire elements emit substantially the same color of light, at least two of which being included in each of a plurality of subpixel sites S₁, S₂ formed on the lower electrode line 200, an upper electrode line 300 arranged to contact the upper portions of the micro-nanofin LED elements 101, 102, 103, 104, and a color conversion layer 700 patterned on the upper electrode line 300 such that each of the plurality of subpixel sites becomes the subpixel site that independently emits any one of blue, green, and red colors.

First, before a detailed description of each configuration, an electrode line for self-aligning a micro-nanofin LED element and emitting light will be described.

The display 1000 according to the first embodiment of the present invention includes the upper electrode line 300 and the lower electrode line 200 disposed opposite to the upper and lower portions with the micro-nanofin LED elements 101, 102, 103, 104 interposed therebetween. Since the upper electrode line 300 and the lower electrode line 200 are not arranged in a horizontal direction, the display 1000 has a very simple electrode design and is easily implemented, compared to a display in which elements are self-aligned through a typical electric field having complex electrode lines that arrange two types of electrodes having micro thickness and width in a horizontal direction within a plane of a limited area so as to have micro or nano-unit interval. In addition, since TFT arrangement is easy, not only active matrix driving but also passive matrix driving, which is x-y matrix driving, is possible, which makes it much easier to implement various types of displays.

The lower electrode line 200 is an assembly electrode for self-aligning the micro-nanofin LED elements so that the upper or lower surfaces in the thickness direction of the micro-nanofin LED elements 101, 102, 103, 104, 105 are in contact with the lower electrode line 200, and may function as one of the driving electrodes provided to emit light of the micro-nanofin LED elements together with the upper electrode line 300 to be described later. Even in a display in which elements are self-aligned through typical electric field induction, micro LEDs are mounted on electrodes spaced apart in the horizontal direction. As the micro LED element emits light by using the same electrode, that is, electrodes spaced apart in the horizontal direction as the driving electrode, an assembly electrode and a driving electrode are possible only with the lower electrode line, whereas the lower electrode line 200 functions an assembly electrode. However, it is distinguished from the display through the typical electric field induction in that the micro-nanofin LED element cannot be emitted using only the lower electrode line 200.

The lower electrode line 200 includes the plurality of electrodes 211, 212, 213, 214 spaced apart in a horizontal direction at a predetermined interval. As a driving electrode provided to emit light of the micro-nanofin LED elements 101, 102, 103, 104, the lower electrode line 200 only needs to be electrically connected to one surface in the thickness direction of the micro-nanofin LED element, and thus, there is little need to design electrodes with a large number of spaced apart in the horizontal direction. Thus, the electrodes 211, 212, 213, 214 may be included in an appropriately set number and spacing in consideration of the length of the element in terms of function as an assembly electrode for self-aligning the micro-nanofin LED elements on the electrode.

On the other hand, a distance between the adjacent electrodes 211, 212 may be smaller than the length of the micro-nanofin LED element 102. If the distance between the two adjacent electrodes is equal to or wider than the length of the micro-nanofin LED element, the micro-nanofin LED element can be self-aligned in a form sandwiched between two adjacent electrodes. In this case, it is not preferable because there is a high possibility that an electrical short circuit may occur due to contact between the electrode side and the photoactive layer exposed on the side surface of the micro-nanofin LED element.

The plurality of electrodes 211, 212, 213, 214 included in the lower electrode line 200 are not limited in specific electrode arrangement, as long as they are arranged spaced apart in the horizontal direction. For example, it may have a structure in which a plurality of electrodes is spaced apart by a predetermined spacing in one direction and arranged side by side.

In addition, when the upper electrode line 300 is designed to be in electrical contact with the upper portions of the micro-nanofin LED elements 102, 103, 104 mounted on the lower electrode line 200, there is no limitation on the number, arrangement, shape, and the like. However, as illustrated in FIG. 1, if the lower electrode lines 200 are arranged side by side in one direction, the upper electrode lines 300 may be arranged to be perpendicular to the one direction, and such an electrode arrangement is an electrode arrangement widely used in a typical display. As the arrangement, there is an advantage that the electrode arrangement and control technology of the typical display field can be used as it is.

On the other hand, although FIG. 1 illustrates that the upper electrode line 300 covers only some elements, such omission is for ease of description, and it is noted that there are more unillustrated upper electrode lines (not shown) 300 disposed on the micro-nanofin LED element.

The lower electrode line 200 and the upper electrode line 300 may have the material, shape, width, and thickness of an electrode used in a typical display, and since they can be manufactured using a known method, the present invention does not particularly limit such method.

For example, the electrode may be aluminum, chromium, gold, silver, copper, graphene, ITO, or an alloy thereof, and may have a width of 2 to 50 µm and a thickness of 0.1 to 100 µm, but the electrode may be appropriately changed in consideration of the size, etc. of a desired display.

Next, the micro-nanofin LED elements 101, 102, 103, 104 disposed between the above-described lower electrode line 200 and the upper electrode line 300 will be described. The micro-nanofin LED elements 101, 102, 103, 104 are arranged such that at least two of the micro-nanofin LED elements are included in the plurality of subpixels S₁, S₂ on the lower electrode line 200, and through this, if the micro-nanofin LED elements 101, 102, 103, 104 are arranged for each subpixel. Through this, even if a defect occurs in some of the micro-nanofin LED elements arranged in each subpixel, a predetermined light can be emitted to all the subpixels, so that the occurrence of defective pixels in the display can be minimized or prevented.

The micro-nanofin LED elements provided per subpixel emit substantially the same color of light. In this case, substantially the same light color does not mean that the wavelengths of the emitted light are completely the same, but generally refers to light belonging to a wavelength range that can be referred to as the same light color. For example, when the light color is blue, it can be seen that all of the micro-nanofin LED elements emitting light belonging to a wavelength range of 420 to 470 nm emit substantially the same light color. The light color emitted by the micro-nanofin LED element provided in the display according to the first embodiment of the present invention may be, for example, blue, white, or UV.

Meanwhile, although the electrode arrangement such as the data electrode and gate electrode provided in a typical display is not illustrated in FIG. 1, the electrode arrangement used in the typical display may be employed for the unillustrated electrode arrangement. Spaces (subpixel sites) in which subpixels are formed, which are determined according to the electrode arrangement of the display, may be formed on the lower electrode line. As an example, although FIG. 1 illustrates that subpixel spaces S₁, S₂ are formed in predetermined areas on two adjacent electrodes, the present invention is not limited thereto.

In addition, the subpixel site may have a unit area of 100 µm×100 µm or less, in another example 30 µm×30 µm or less, and in another example 20 µm×20 µm or less. Since the unit area of this size is reduced compared to the unit subpixel area of the display using the LED, it is possible to achieve a large area while minimizing the area ratio occupied by the LED, which can be advantageous for realizing a high-resolution display. Meanwhile, the unit area of each subpixel site may be different from each other. In addition, a separate surface treatment or grooves may be formed on the surfaces of the subpixel sites.

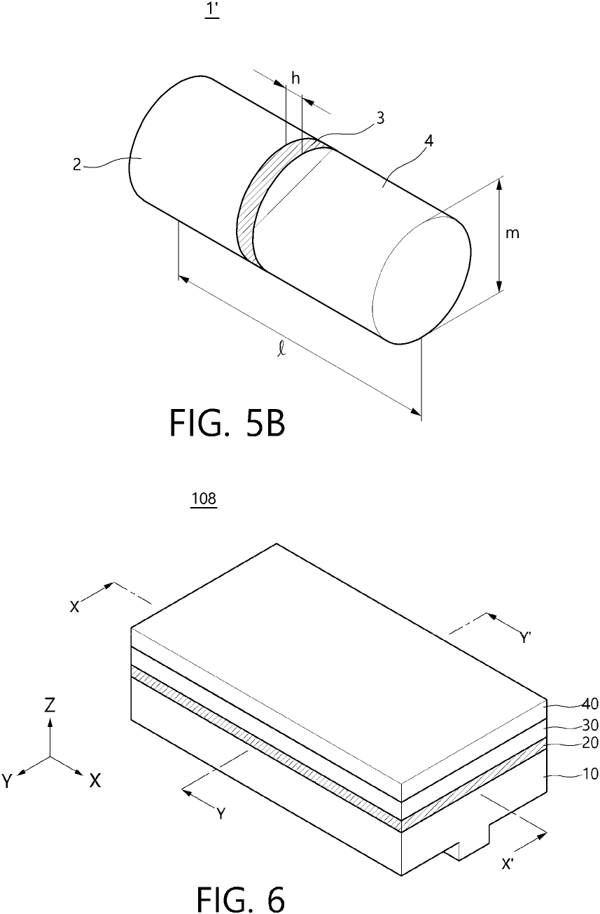

The micro-nanofin LED elements 101, 102, 103, 104, which are arranged at least two in each subpixel space, have an element length greater than a thickness and are an element in which a first conductive semiconductor layer, a photoactive layer, and a second conductive semiconductor layer are stacked in the thickness direction. More specifically, FIG. 5B illustrates a micro-nanofin LED element 1 according to an embodiment of the present invention. When, based on the mutually perpendicular x, y, and z axes, the x-axis direction is the length, the y-axis direction is the width, and the z-axis direction is the thickness, the micro-nanofin LED element 1 has a predetermined shape in the x-y plane consisting of a length and a width, is a rod-type element in which the direction perpendicular to the plane becomes the thickness direction, the length of the element is the major axis, and the thickness is the minor axis, and may be an element in which the first conductive semiconductor layer 2, the photoactive layer 3, and the second conductive semiconductor layer 4 may be sequentially stacked in the thickness direction. The micro-nanofin LED element 1 having such a structure has an advantage of securing a wider emission area due to a plane consisting of a length and a width even if the thickness of the photoactive layer 3 in the portion exposed to the side surface is thin. In addition, due to this, the emission area of the micro-nanofin LED element 1 included in the embodiment of the present invention may have an emission area exceeding twice the area of the longitudinal cross-section of the micro-nanofin LED element. Here, the longitudinal cross-section is a cross-section parallel to the X-axis direction, which is the longitudinal direction, and in the case of an element having a constant width, it may be the x-y plane.

Specifically, when describing by comparing FIGS. 5A and 5B, the micro-nanofin LED element 1 illustrated in FIG. 5A and the horizontally arranged rod-type element 1 ” illustrated in FIG. 5B both have a structure in which the first conductive semiconductor layer 2, the photoactive layer 3, and the second conductive semiconductor layer 4 are stacked, and are rod-type elements in which the length (ℓ) and the thickness (m) are the same, and the thickness (h) of the photoactive layer is also the same. However, in the first rod-type element 1, the first conductive semiconductor layer 2, the photoactive layer 3, and the second conductive semiconductor layer 4 are stacked in the thickness direction, which is the vertical direction, while in the horizontally arranged rod-type element 1′ structurally different from the first rod-type element 1, each layer is stacked in the longitudinal direction, which is the horizontal direction.

However, the two elements 1, 1′ have a large difference in the emission area. Assuming that, for example, the length (ℓ) is 4500 nm, the thickness (m) is 600 nm, and the thickness (h) of the photoactive layer 3 is 100 nm, the ratio of the surface area (which corresponds the emission area) of the photoactive layer 3 of the first rod-type element 1 and the surface area of the photoactive layer 3 of the second rod-type element 1′ is 6.42 µm²: 0.6597 µm². Thus, the emission area of the first rod-type element 1, which is a micro-nanofin LED element, is 9.84 times larger. In addition, for the ratio of the surface area of the photoactive layer 3 exposed to the outside in the emission area of the total photoactive layer, the first rod-type element 1 is similar to the second rod-type element 1′, but since the increased absolute value of the unexposed surface area of the photoactive layer 3 is much larger, the effect of the exposed surface area on the excitons is much reduced. Thus, since the first rod-type element 1, which is the micro-nanofin LED element, has a much smaller effect of surface defects on excitons compared to the second rod-type element 1′, which is a horizontally arranged rod-type element. Therefore, it can be evaluated that the first rod-type element 1, which is the micro-nanofin LED element, is significantly superior to the second rod-type element 1′, which is the horizontally arranged rod-type element, in terms of luminous efficiency and luminance.

In addition, in the case of the horizontally arranged rod-type element 1′, a wafer on which a conductive semiconductor layer and a photoactive layer are stacked in the thickness direction is etched in the thickness direction. As a result, a long length of the element corresponds to the wafer thickness. In order to increase the length of the element, an increase in the etched depth is unavoidable. The greater the etch depth, the higher the possibility of defects on the element surface. As a result, even if the area of the exposed photoactive layer is small compared to the micro-nanofin LED element 1, the horizontally arranged rod-type element 1′ has a higher possibility of surface defects. Thus, considering that the luminous efficiency decreases due to the increase in the possibility of surface defects, the micro-nanofin LED element 1 can be significantly superior in luminous efficiency and luminance.

Furthermore, a movement distance of the holes injected from any one of the first conductive semiconductor layer 2 and the second conductive semiconductor layer 4 and the electrons injected from the other one in the micro-nanofin LED element 1 is shorter than the movement distance in the horizontally arranged element 1′, so that the probability of electrons and/or holes being captured by defects on the wall during electron and/or hole movement is reduced, thereby minimizing emission loss, and advantageously minimizing emission loss due to electron-hole velocity imbalance. In addition, in the case of the horizontally arranged element 1′, a strong optical path behavior occurs due to the circular rod-type structure, so the path of the light generated by electron-holes resonates in the longitudinal direction, so that light is emitted from both ends in the longitudinal direction, and thus, a front luminous efficiency is not good due to the strong side luminous profile when the elements are arranged to be placed lying down. On the other hand, in the case of the micro-nanofin LED element 1, light is emitted from the upper and lower surfaces, so excellent front luminous efficiency is expressed and thereby the front luminance of the display can be advantageously improved.

In the micro-nanofin LED element included in an embodiment of the present invention, the plane has a rectangular shape as illustrated in FIG. 5A, but the shape is not limited thereto. It is noted that the shape can be employed without limitation, from general rectangular shapes such as rhombus, parallelogram, trapezoid, etc. to oval, etc.

In addition, the micro-nanofin LED element 1,101,102,103,104 according to an embodiment of the present invention has a size of micro or nano units in length and width. For example, the element may have a length of 1000 to 10000 nm, and a width of 100 to 3000 nm. In addition, the thickness may be 100 to 3000 nm. The standard of the length and width may be different depending on the shape of the plane. For example, when the plane is a rhombus or a parallelogram, one of the two diagonals may be the length and the other may be the width, and in the case of a trapezoid, the longest of the height, upper and lower side surfaces may be the length, and the shorter one perpendicular to the longer one may be the width. Alternatively, when the shape of the plane is an ellipse, the major axis of the ellipse may be the length and the minor axis may be the width.

In this case, a ratio of the length and thickness of the micro-nanofin LED element 1,101,102,103,104 may be 3: 1 or more, more preferably 6: 1 or more, and thus the length may be greater than the thickness, and through this, there is the advantage in that the element can be self-aligned more easily on the electrode through an electric field. If the ratio of the length and thickness of the micro-nanofin LED element 100 is reduced to less than 3: 1, it may be difficult to self-align the element on the electrode through an electric field, and the element is not fixed on the electrode. There is a possibility that an electrical contact short circuit caused by a defect. However, the ratio of the length and the thickness may be 15: 1 or less, and through this, it may be advantageous to achieve the object of the present invention, such as optimization of a rotation torque that is self-alignment through an electric field.

In addition, the ratio of the length and the width in the plane may also be 3: 1 or more, more preferably 6: 1 or more, so the length may be greater. Through this, there is the advantage of more easily self-aligning the element on the electrode through an electric field. However, the ratio of the length and the width may be 15: 1 or less, which may be advantageous for optimization of the rotation torque that is self-alignment through the electric field.

In addition, the width of the micro-nanofin LED element 1,101,102,103,104 may be greater than or equal to the thickness, through this, when the micro-nanofin LED element 1,101,102,103,104 is aligned on the two electrodes of the lower electrode line by using an electric field in a manufacturing method of a full-color display manufacturing method to be described later, there is an advantage of minimizing or preventing alignment by lying on the side surface. If the micro-nanofin LED element is aligned on its side surface, even if alignment and mounting are achieved in which one end and the other end contact two different electrodes, respectively, the element may not emit light due to an electrical short circuit that occurs as the photoactive layer exposed on the side surface of the element comes into contact, which may reduce display luminance or generate defective pixels.

In addition, the micro-nanofin LED element 1, 101, 102, 103, 104 may be an element having different sizes at both ends in the longitudinal direction, for example, a rod-type element having a rectangular plane of an equilateral trapezoid whose length, i.e., height is greater than the upper and lower side surfaces. Depending on the length difference between the upper side surface and the lower side surface, a difference between positive and negative charges accumulated at both ends of the element in the longitudinal direction may occur as a result, which may make the self-alignment through an electric field easier.

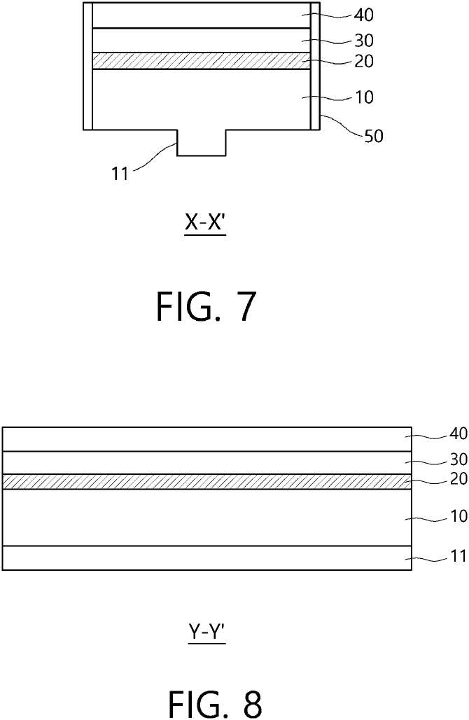

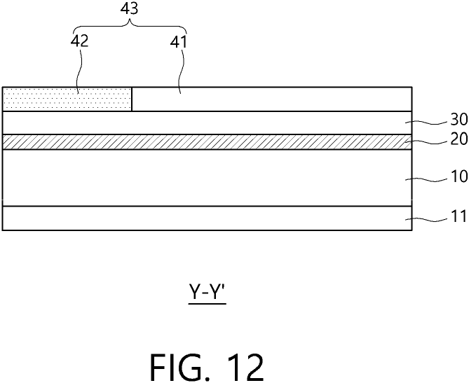

In addition, as illustrated in FIGS. 6 to 8 and 10 to 12, the lower surface of the first conductive semiconductor layer 10 of the micro-nanofin LED element 108, 109 includes a protrusion 11 that may be formed in the longitudinal direction of the element while having a predetermined width and thickness. Although the protrusion 11 will be described in detail in the description of the manufacturing method to be described later, the protrusion may be formed as a result of horizontally etching inward from both side surfaces of the lower end of the etched LED portion in order to remove the etched LED portion from a wafer after etching the wafer in the thickness direction. The protrusion 11 may help to perform an improvement function for the extraction of the front emission of the micro-nanofin LED element 108, 109. In addition, when the micro-nanofin LED element 108, 109 is self-aligned on the lower electrode line 200, the protrusion 11 may help to control the alignment of the element such that the opposite surface (for example, the exposed surface of the second conductive semiconductor layer) opposite to the one surface of the element on which the protrusion 11 is formed is positioned on the lower electrode line 200. Furthermore, after the opposite surface is positioned on the lower electrode line 200, the upper electrode line 300 is formed on the upper surface where the protrusion 11 of the micro-nanofin LED element 108, 109 is formed, the protrusions 11 may be advantageous in improving the mechanical coupling force between the upper electrode line 300 and the micro-nanofin LED element 108, 109 as the contact area between the formed upper electrode line 300 and the protrusion 11 increases.

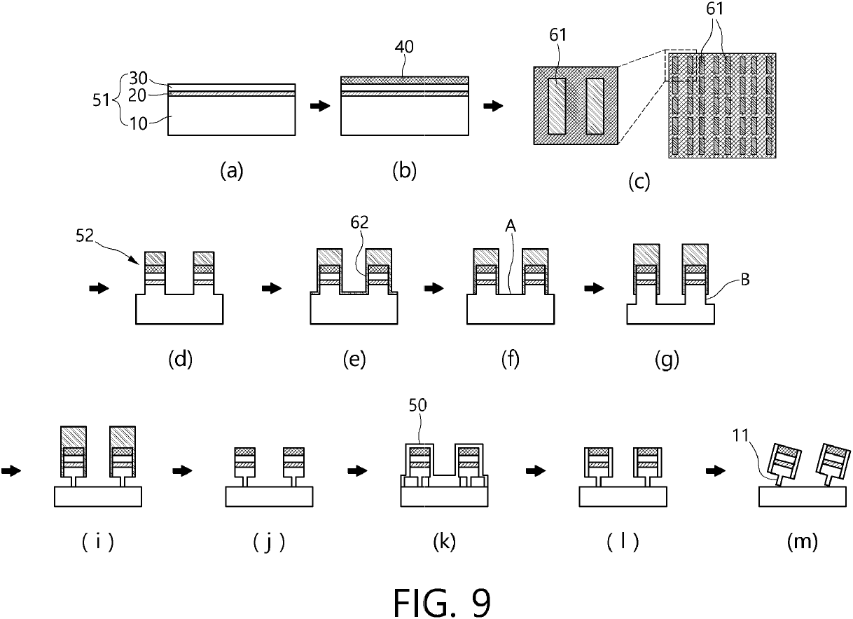

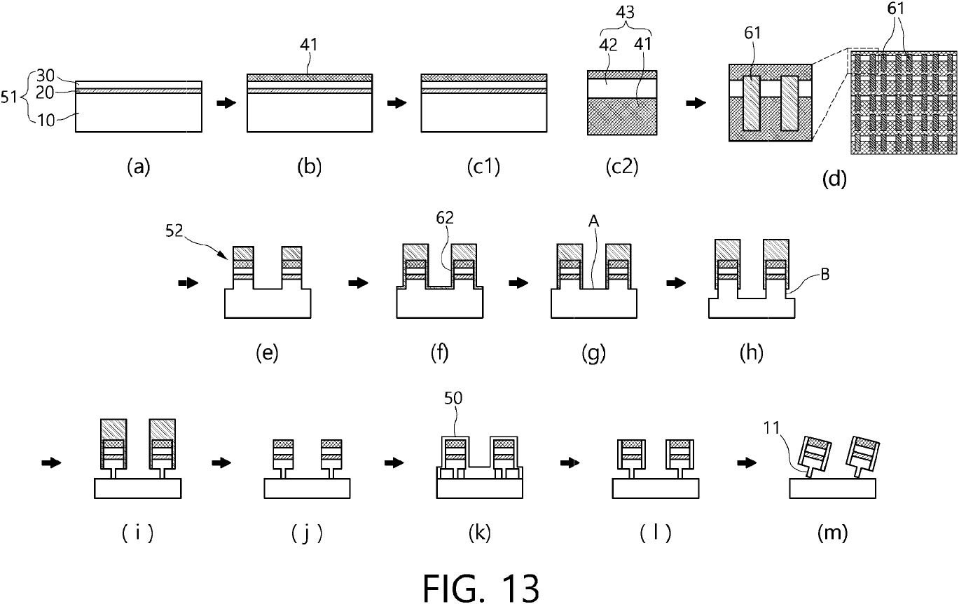

In this case, the width of the protrusion 11 may be formed to be 50% or less, more preferably, 30% or less of the width of the micro-nanofin LED element 108, 109, so that the separation of the etched portion of the micro-nanofin LED element on the LED wafer can be made easier. If the protrusion is formed exceeding 50% of the width of the micro-nanofin LED element 108, 109, it may not be easy to separate the etched portion of the micro-nanofin LED element on the LED wafer, and the separation of unintended portion may be occurred, which may cause a degradation in mass productivity, and there is a risk that the uniformity in the micro-nanofin LED elements produced in large numbers may be reduced. Meanwhile, the width of the protrusion 11 may be formed to be 10% or more of the width of the micro-nanofin LED element 108, 109. If the width of the protrusion is formed to be less than 10% of the width of the micro-nanofin LED element 108, 109, the separation on the LED wafer may be easy, but during side etching (see FIG. 9(g)/FIG. 9(i)), FIG. 13(h) / FIG. 13(i)) to be described later, due to excessive etching, there is a risk that even a portion of the first conductive semiconductor layer that should not be etched may be etched, and the effect according to the above-described protrusion 11 may not be expressed. In addition, there is a risk of separation by the wet etching solution, and there is a problem in that the micro-nanofin LED element dispersed in the high-risk etching solution having a strong basic property has to be separated from the wet etching solution for cleaning. On the other hand, the thickness of the protrusion 11 may have a thickness of 10 to 30% of the thickness of the first conductive semiconductor layer, through which the first conductive semiconductor layer can be formed to a desired thickness and quality, which may be more advantageous to express the effect through the protrusion 11. Here, the thickness of the first conductive semiconductor layer refers to a thickness based on the lower surface of the first conductive semiconductor layer on which the protrusion is not formed.

As a specific example, the protrusion 11 may have the width of 50 to 300 nm, and the thickness of 50 to 400 nm.

According to an embodiment of the present invention, the micro-nanofin LED element 1, 101, 102, 103, 104 may further include an electrode layer or a polarization inducing layer on the second conductive semiconductor layer 4. The polarization inducing layer includes a first polarization inducing layer formed on one end in the longitudinal direction of the element, and a second polarization inducing layer having an electrical polarity different from that of the first polarization inducing layer formed on the other end in the longitudinal direction of the element.

Referring to FIGS. 6 to 8, each layer will be described in detail based on the micro-nanofin LED element 108 in which the electrode layer 40 is formed on the second conductive semiconductor layer 30. The micro-nanofin LED element 108 includes a first conductive semiconductor layer 10 and a second conductive semiconductor layer 30. The conductive semiconductor layer used may be used without limitation if it is a conductive semiconductor layer employed in a typical LED element used for a display. According to a preferred embodiment of the present invention, any one of the first conductive semiconductor layer 10 and the second conductive semiconductor layer 30 may include at least one n-type semiconductor layer, and the other conductive semiconductor layer may include at least one p-type semiconductor.

When the first conductive semiconductor layer 10 includes an n-type semiconductor layer, the n-type semiconductor layer may include a semiconductor material having an empirical formula of InₓAl_{y}Ga₁_{-x-y}N (0≤x≤1, 0≤y≤1, and 0≤x+y≤1), for example, at least one selected from among InAlGaN. GaN, AlGaN, InGaN, AN, InN, and the like and may be doped with a first conductive dopant (for example, Si, Ge, Sn, etc.). According to one preferred embodiment of the present invention, the first conductive semiconductor layer 10 may have a thickness of 1.5 to 5 µm, but the present invention is not limited thereto.

When the second conductive semiconductor layer 30 includes a p-type semiconductor layer, the p-type semiconductor layer may include a semiconductor material having an empirical formula of InₓAl_{y}Ga_{1-x-y}N (0≤x≤1, 0≤y≤1, and 0≤x+y≤1), for example, at least one selected from among InAlGaN, GaN, AlGaN, InGaN, AlN, InN, and the like, and may be doped with a second conductive dopant (for example, Mg). According to one preferred embodiment of the present invention, the second conductive semiconductor layer 30 may have a thickness of 0.01 to 0.30 µm, but the present invention is not limited thereto.

According to an embodiment of the present invention, one of the first conductive semiconductor layer 10 and the second conductive semiconductor layer 30 includes a p-type GaN semiconductor layer, and the other includes an n-type GaN semiconductor layer, and the p-type GaN semiconductor layer may have a thickness of 10 to 300 nm, and the n-type GaN semiconductor layer may have a thickness of 100 to 3000 nm, through which the movement distance of the holes injected into the p-type GaN semiconductor layer and the electrons inserted into the n-type GaN semiconductor layer is shorter compared to the rod-type element in which the semiconductor layer and the photoactive layer are stacked in the longitudinal direction as illustrated in FIG. 5. Through this, the probability of electrons and/or holes being captured by defects on the wall during movement is reduced, thereby minimizing emission loss, and it may be advantageous to minimize emission loss due to electron-hole velocity imbalance.

Next, the photoactive layer 20 is formed on the first conductive semiconductor layer 10 and may be formed to have a single or multi-quantum well structure. A photoactive layer included in a typical LED element used for a light, a display, and the like may be used as the photoactive layer 20 without limitation. A clad layer (not shown) doped with a conductive dopant may be formed on and/or below the photoactive layer 20, and the clad layer doped with the conductive dopant may be implemented as an AlGaN layer or an InAlGaN layer. In addition, a material such as AlGaN or AlInGaN may be used for the photoactive layer 20. In the photoactive layer 20, when an electric field is applied to an element, electrons and holes moving from the conductive semiconductor layers positioned on and below the photoactive layer to the photoactive layer are combined to generate electron-hole pairs in the photoactive layer, thereby emitting light. According to one preferred embodiment of the present invention, the photoactive layer 20 may have a thickness of 30 to 300 nm, but the present invention is not limited thereto.

Next, an electrode layer included in a typical LED element used for a display may be used as the electrode layer 40 further formed on the second conductive semiconductor layer 30 described above without limitation. The electrode layer 40 may be made of Cr, Ti, Al, Au, Ni, ITO, and an oxide or alloy thereof alone or in combination, but the electrode layer 40 may be preferably a transparent material in order to minimize emission loss. An example may be the ITO. In addition, the thickness of the electrode layer 40 may be 50 to 500 nm, but is not limited thereto.

In addition, according to an embodiment of the present invention, a protective film 50 formed on the side surface of the micro-nanofin LED element 108 to cover the exposed surface of the photoactive layer 20 may be further included. The protective film 50 is a film for protecting the exposed surface of the photoactive layer 20, and covers at least all the exposed surface of the photoactive layer 20, for example, both side surfaces, front end, and rear end of the micro-nanofin LED element 108. The protective film 50 may include at least one from among silicon nitride (Si₃N₄), silicon dioxide (SiO₂), aluminum oxide (Al₂O₃), hafnium oxide (HfO₂), zirconium oxide (ZrO₂), yttrium oxide (Y₂O₃), titanium dioxide (TiO₂), aluminum nitride (AlN), and gallium nitride (GaN), more preferably the material made of the above component, or may be transparent, but is not limited thereto. According to a preferred embodiment of the present invention, the thickness of the protective film may be 5 to 100 nm, but is not limited thereto.

The micro-nanofin LED element 108 of FIGS. 6 to 8 may be manufactured by a manufacturing method described below, but is not limited thereto. Referring to FIG. 9, the micro-nanofin LED element 108 may be implemented by including the steps of (L1) preparing a LED wafer 51 in which the first conductive semiconductor layer 10, the photoactive layer 20, and the second conductive semiconductor layer 30 are sequentially stacked on a substrate (not shown), (L2) forming the electrode layer 40 on the second conductive semiconductor layer 30 of the LED wafer 51, (L3) forming a plurality of micro-nanofin LED pillars 52 by etching the LED wafer 51 in the thickness direction so that each element has a plan with a nano- or micro-sized length and width and the thickness perpendicular to the plane is smaller than the length, and (L4) separating the plurality of micro-nanofin LED pillars 52 from the substrate.

First, as step (L1), the step of preparing the LED wafer 51 in which the first conductive semiconductor layer 10, the photoactive layer 20, and the second conductive semiconductor layer 30 are sequentially stacked on a substrate (not shown) may be performed.

The thickness of the first conductive semiconductor layer 10 in the LED wafer 51 may be thicker than the thickness of the first conductive semiconductor layer 10 in the above-described micro-nanofin LED element 100. In addition, each layer in the LED wafer 51 may have a c-plane crystal structure.

In addition, the LED wafer 51 may be subjected to a cleaning process, and since a cleaning process and cleaning solution of a typical wafer may be appropriately applied in the cleaning process, the present invention is not particularly limited thereto. The cleaning solution may be, for example, isopropyl alcohol, acetone, and hydrochloric acid but is not limited thereto.

Next, as step (L2), as illustrated in FIG. 9(b), the step of forming the electrode layer 40 on the second conductive semiconductor layer 30 of the LED wafer 51 may be performed. The first electrode layer 40 may be formed through a typical method of forming an electrode on a semiconductor layer and may be formed by, for example, deposition through sputtering. The material of the first electrode layer 40 may be, for example, ITO as described above, and the first electrode layer 40 may be formed to have a thickness of about 150 nm. The first electrode layer 40 may be further subjected to a rapid thermal annealing process after a deposition process. As an example, the first electrode layer 40 may be processed at a temperature of 600° C. for 10 minutes. However, since the rapid thermal annealing process may be appropriately adjusted in consideration of the thickness, material, etc. of the electrode layer, the present invention is not particularly limited thereto.

Next, as step (L3) of the present invention, the step of forming the plurality of micro-nanofin LED pillars 52 by etching the LED wafer 51 in the thickness direction so that each element has a plane having a length and width of nano or micro size and the thickness perpendicular to the plane is smaller than the length may be performed.

Specifically, step (L3) may be performed by including the steps of (L3-1) forming a mask pattern layer 61 on the upper surface of the electrode layer 40 so that each element is a plane having a predetermined shape having a length and width of nano or micro size (FIG. 9(c)), (L3-2) forming the plurality of micro-nanofin LED pillars 52 by etching the first conductive semiconductor layer 10 to a partial thickness in the thickness direction along the pattern (FIG. 9(d)), (L3-3) forming an insulating film 62 to cover the exposed side surface of the micro-nanofin LED pillar 52 (FIG. 9(e)), (L3-4) removing a portion of the insulating film 62 formed on the upper portion of the first conductive semiconductor layer 10 to expose the upper surface (A in FIG. 9(f)) of the first conductive semiconductor layer 10 between the adjacent micro-nanofin LED pillars 52 (FIG. 9(f)), (L3-5) forming a portion (B in FIG. 9(g)) of the first conductive semiconductor layer with the side surface exposed by a predetermined thickness below the first conductive semiconductor layer of the micro-nanofin LED pillar on which the insulating film 62 is formed by further etching the first conductive semiconductor layer 10 in the thickness direction through the exposed upper portion (A in FIG. 9(f)) of the first conductive semiconductor layer (FIG. 9(g)), (L3-6) etching the portion (B in FIG. 9(g)) of the first conductive semiconductor layer with side surface exposed from both side surfaces toward the center (FIG. 9(i)), and (L3-7) removing the mask pattern layer 61 disposed on the upper portion of the electrode layer 40 and the insulating film 62 covering the side surface (FIG. 9(j)).

First, as step (L3-1), the step of forming the mask pattern layer 61 on the upper surface of the electrode layer 40 so that each element is a plane having a predetermined shape having a length and width of nano or micro size (FIG. 9 (c)) may be performed.

The mask pattern layer 61 is a layer patterned to have a desired planar shape of the LED element to be implemented, and may be formed of a known method and material used for etching an LED wafer. The mask pattern layer 61 may be, for example, a SiO₂ hard mask pattern layer. Briefly, the mask pattern layer 61 may be formed by a method of forming an unpatterned SiO₂ hard mask layer on the electrode layer 40, forming a metal layer on the SiO₂ hard mask layer, forming a predetermined pattern on the metal layer, etching the metal layer and the SiO₂ hard mask layer along the pattern, and removing the metal layer.

The mask layer is a layer from which the mask pattern layer 61 is derived. For example, SiO₂ may be formed through deposition. The mask layer may have a thickness of 0.5 to 3 µm, for example, 1.2 µm. In addition, the metal layer may be, for example, an aluminum layer, and the aluminum layer may be formed through deposition. The predetermined pattern formed on the formed metal layer is for realizing the pattern of the mask pattern layer, and may be a pattern formed by a typical method. For example, the pattern may be formed through photolithography using a photosensitive material or may be a pattern formed through a known nanoimprinting method, laser interference lithography, electron beam lithography, or the like. Thereafter, the metal layer and the SiO₂ hard mask layer are etched along the formed pattern. For example, the metal layer may be etched using an inductively coupled plasma (ICP), the SiO₂ hard mask layer or the imprinted polymer layer may be etched using dry etching method such as a reactive ion etching (RIE).

Next, the step of removing the metal layer or other photosensitive material layer remained on the upper portion of the etched SiO₂ hard mask layer, or the remaining polymer layer according to the imprint method may be performed. The removal may be performed through a typical wet etching or dry etching method depending on the material, and detailed description thereof will be omitted in the present invention.

FIG. 9 (c) illustrates a plan view of the SiO₂ hard mask layer 61 patterned on the electrode layer 40, and then, as illustrated in FIG. 5 (d), step 3-2) of forming the plurality of micro-nanofin LED pillars 52 by etching the first conductive semiconductor layer 10 to a partial thickness in the thickness direction of the LED wafer 51 along the pattern may be performed. The etching may be performed through a typical dry etching method such as ICP.

Thereafter, as step (L3-3), the step of forming the insulating film 62 to cover the exposed side surface of the micro-nanofin LED pillar 52 may be performed, as illustrated in FIG. 9(e). The insulating film 62 coated on the side surface may be formed through deposition, and the material thereof may be, for example, SiO₂, but is not limited thereto. The insulating film 62 functions as a side mask layer, and specifically, in the process of etching the portion (B) of the first conductive semiconductor layer to separate the micro-nanofin LED pillar 52 as illustrated in FIG. 9(i), the insulating film 62 functions to leave the side surface of the micro-nanofin LED pillar 52 and prevent damage due to the etching process. The insulating film 62 may have a thickness of 100 to 600 nm, but is not limited thereto.

Next, as step (L3-4), the step of removing the portion of the insulating film 62 formed on the first conductive semiconductor layer 10 may be performed in order to expose the upper surface (A in FIG. 9(f)) of the first conductive semiconductor layer 10 between the adjacent micro-nanofin LED pillars 52, as illustrated in FIG. 9(f). The insulating film 62 may be removed through an appropriate etching method in consideration of the material, and as an example, the insulating film 62 made of SiO₂ may be removed through a dry etching such as RIE.

Next, as step (L3-5), the step of forming the portion (B in FIG. 9(g)) of the first conductive semiconductor layer in which the side surface is exposed by a predetermined thickness below the first conductive semiconductor layer of the micro-nanofin LED pillar on which the insulating film 62 is formed by further etching the first conductive semiconductor layer 10 in the thickness direction through the exposed upper portion (A in FIG. 9(f)) of the first conductive semiconductor layer may be performed, as illustrated in FIG. 9(g). As described above, the exposed portion (B) of the first conductive semiconductor layer 10 is a portion on which side etching is performed in a direction horizontal to the substrate in a step to be described later. The process of further etching the first conductive semiconductor layer 10 in the thickness direction may be performed by, for example, a dry etching method such as ICP.

Thereafter, as step (L3-6), the step of side-etching the portion (B of FIG. 9(g)) of the first conductive semiconductor layer with the side surface exposed in a horizontal direction to the substrate may be performed, as illustrated in FIG. 9(i). The side etching may be performed through wet etching. For example, the wet etching may be performed at a temperature of 60 to 100° C. using a tetramethylammonium hydroxide (TMAH) solution.

Thereafter, after wet etching in the lateral direction is performed, as step (L3-7), the step of removing the mask pattern layer 61 disposed on the electrode layer 40 and the insulating film 62 covering the side surface may be performed, as illustrated in FIG. 9(j). Both the materials of the mask pattern layer 61 and insulating film 62 disposed on the upper portion may be SiO₂, and may be removed through wet etching. For example, the wet etching may be performed using a buffer oxide etchant (BOE).

According to an embodiment of the present invention, as step (L5) between steps (L3) and (L4) described above, the step of forming the protective film 50 on the side surfaces of the plurality of micro-nanofin LED pillars may be further performed. The protective film 50 may be formed by, for example, deposition as illustrated in FIG. 9(k), and may have a thickness of 10 to 100 nm, for example 40 nm, and the material may be, for example, alumina. When using alumina, an atomic layer deposition (ALD) method may be used as an example of the deposition. In addition, in order to form the deposited protective film 50 only on the side surfaces of the plurality of micro-nanofin LED pillars, the protective film 50 positioned on the remaining portions except for the side surfaces is removed by etching, for example, dry etching such as ICP. On the other hand, it is noted that although FIG. 9(1) illustrates that the protective film 50 surrounds the entire side surfaces, the protective film 50 may not be formed on all or part of the remaining portions except for the photoactive layer on the side surface.

Next, as step (L4) according to the present invention, the step of separating the plurality of micro-nanofin LED pillars from the substrate may be performed, as illustrated in FIG. 9(m). The separation may be cutting using a cutting mechanism or separation using an adhesive film, and the present invention is not particularly limited thereto.

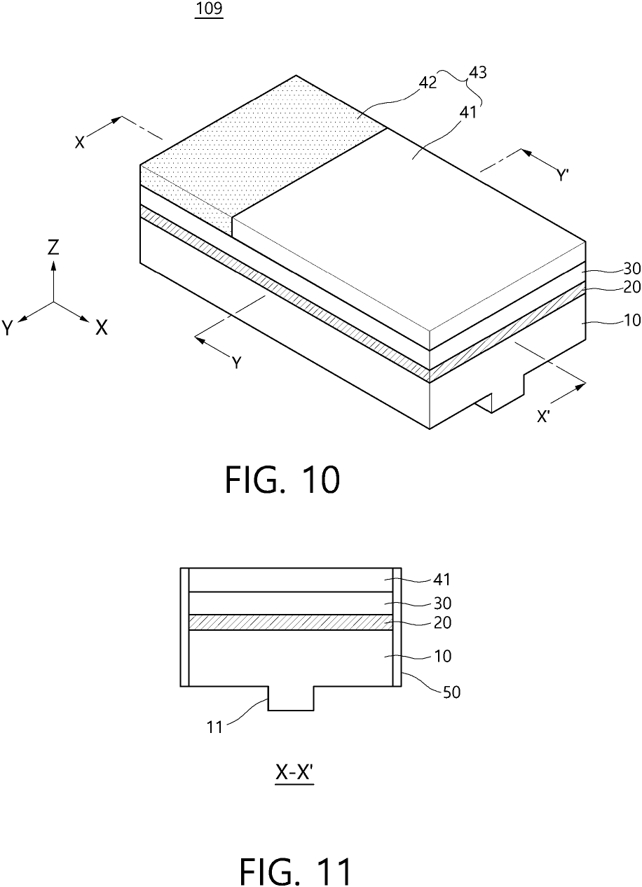

On the other hand, as illustrated in FIGS. 10 to 12 differently from the above-described FIGS. 6 to 8, the micro-nanofin LED element 109 may further include the polarization inducing layer 43 on the second conductive semiconductor layer 30, which includes a first polarization inducing layer 41 formed on one end in the longitudinal direction and a second polarization inducing layer 42 having an electrical polarity different from that of the first polarization inducing layer 41 formed on the other end in the longitudinal direction. The micro-nanofin element 109 illustrated in FIGS. 10 to 12 is different from the micro-nanofin element 108 illustrated in FIGS. 6 to 8 in that the polarization inducing layer 43, instead of the electrode layer 40, is formed on the second conductive semiconductor layer 30.

The polarization inducing layer 43 is a layer that facilitates self-alignment by an electric field by allowing both ends thereof to have different electrical polarities in the longitudinal direction of the element, and at the same time, may increases conductivity and function as an electrode layer when a material such as a metal is used. The polarization inducing layer 43 may have the first polarization inducing layer 41 disposed on one end along the longitudinal direction of the element, and the second polarization inducing layer 42 disposed on the other end, and the first polarization inducing layer 41 and the second polarization inducing layer 42 may have different electrical polarities. For example, the first polarization inducing layer 41 may be ITO, and the second polarization inducing layer 42 may be a metal or a semiconductor. In addition, the thickness of the polarization inducing layer 43 may be 50 to 500 nm, but is not limited thereto. The first polarization inducing layer 41 and the second polarization inducing layer 42 may be disposed in the same area by dividing the upper surface of the second conductive semiconductor layer 30 in two, but is not limited thereto. Either one of the first polarization inducing layer 41 and the second polarization inducing layer 42 may be disposed to have a larger area.

The polarization inducing layer 43 may be provided by performing step of (M2) forming the polarization inducting layer 43 patterned so that regions having different electrical polarities are adjacent to each other on the second conductive semiconductor layer 30 of the LED wafer 51, instead of the (L2) step described above.

More specifically, step (M2) is described with reference to FIG. 13. Step (M2) may be performed by including the steps of (M 2-1) forming the first polarization inducing layer 41 on the second conductive semiconductor layer 30 (FIG. 13(b)), (M2-2) etching the first polarization inducing layer 41 in the thickness direction along a predetermined pattern, and (M2-3) forming the second polarization inducing layer on the etched intaglio portion (FIG. 13(d), FIG. 13(c2)).

First, as tep (M2-1), the step of forming the first polarization inducing layer 41 on the second conductive semiconductor layer 30 may be performed. The first polarization inducing layer 41 may be a typical electrode layer formed on a semiconductor layer, and may be, for example, Cr, Ti, Ni, Au, ITO, etc., preferably ITO in terms of transparency. The first polarization inducing layer 41 may be formed through a typical method of forming an electrode, and may be formed by, for example, deposition through sputtering. For example, when ITO is used, it may be deposited to a thickness of about 150 nm, and may be further subjected to a rapid thermal annealing process after the deposition process. For example, the treatment may be performed at 600° C. for 10 minutes, but since the thickness and material of the first polarization inducing layer 41 may be appropriately adjusted, the present invention is not particularly limited thereto.

Next, as step (M2-2), the step of etching the first polarization inducing layer 41 in a thickness direction according to a predetermined pattern is performed. This step is the step of preparing a region at which the second polarization inducing layer 42 to be described later is to be formed, and the pattern may be formed in consideration of the area ratio and arrangement of the first polarization inducing layer 41 and the second polarization inducing layer 42 in the element. For example, the pattern may be formed such that the first polarization inducing layer 41 and the second polarization inducing layer 42 are alternately arranged side by side as illustrated in FIG. 13(d). Since the pattern can be formed by appropriately applying a typical photolithography method or nanoimprinting method, a detailed description thereof will be omitted in the present invention.

The etching may be performed by employing an appropriate known etching method in consideration of the selected material of the first polarization inducing layer 41. For example, when the first polarization inducing layer 41 is ITO, it may be etched through wet etching. In this case, the etched thickness may be etched up to the upper surface of the second conductive semiconductor layer 30, that is, all the ITO may be etched in the thickness direction, but is not limited thereto. Specifically, only a portion of the ITO is etched in the thickness direction, and the second polarization inducing layer 42 may be formed on the etched intaglio portion, in this case it is noted that one upper layer of the element may be formed in a two-layer structure in which the first polarization inducing layer 41 of ITO and the second polarization inducing layer 42 are stacked.

Next, as step (M2-3), the step of forming the second polarization inducing layer 42 on the etched intaglio portion may be performed. The second polarization inducing layer 42 has a material having a different electrical polarity from that of the selected first polarization inducing layer 41, and a material used in a typical LED may be used as for the second polarization inducing layer 42 without limitation. For example, the material may be a metal or a semiconductor, specifically nickel or chromium. As the method for forming these, a known method such as deposition may be appropriately employed according to the material, so that the present invention is not particularly limited thereto.

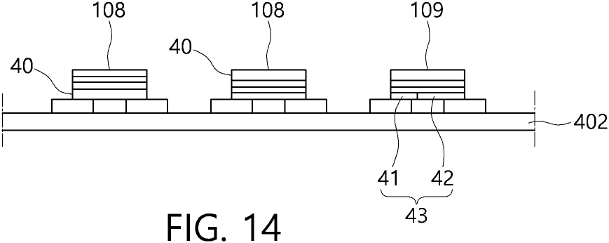

Meanwhile, as illustrated in FIGS. 1 and 2, the micro-nanofin LED element 101, 102, 103, 104 may be disposed on one surface in the thickness direction on each of two electrodes 201, 202 adjacent in the lower electrode line 200, that is, the element may be disposed such that the first conductive semiconductor layer or the second conductive semiconductor layer contact the electrode. In addition, when the electrode layer 40 or the polarization inducing layer 43 is further included, as illustrated in FIG. 14, the first micro-nanofin LED element 108 may be disposed such that the electrode layer 40 contacts the upper surface of the lower electrode line formed on the substrate 402, or the first conductive semiconductor layer contacts the upper surface of the lower electrode line, and the electrode layer 40 contacts the upper electrode line (not shown). Meanwhile, in the case of the second micro-nanofin LED element 109 further including the polarization inducing layer 43, the polarization inducing layer 43 may be disposed on the upper surface of the lower electrode line. However, it is noted that when a plurality of second micro-nanofin LED elements 109 is included, the polarization inducing layers 43 of all the second micro-nanofin LED elements 109 are not disposed to contact the upper surface of the lower electrode line, but the polarization inducing layer 43 may be disposed in contact with the lower electrode line with a high probability compared to the first micro-nano-fin LED element 108.

In addition, according to an embodiment of the present invention, as illustrated in FIG. 2, a conductive metal layer 500 that connects between any one layer of the micro-nanofin LED element 102, 103, 104 contacting the lower electrode line 200 and the lower electrode line 200 may be further included to reduce contact resistance between the micro-nanofin LED elements 102, 103, 104 disposed on the lower electrode lines 200. The any one layer of the micro-nanofin LED element 102, 103, 104 means the upmost layer or lowermost layer of the element, for example, the first conductive semiconductor layer 10 or the second conductive semiconductor layer 30. Alternatively, in the case of the element further including the electrode layer 40 or the polarization inducing layer 43 on the second conductive semiconductor layer 30, the any one layer may be the first conductive semiconductor layer 10, the electrode layer 40 or the polarization inducing layer 43. In addition, the conductive metal layer 500 may be a conductive metal layer such as silver, aluminum, or gold, and may be formed, for example, to have a thickness of about 10 nm.

In addition, an insulating layer 600 may be further included in a space between the micro-nanofin LED element 102, 103, 104 self-aligned on the lower electrode line 200 and the upper electrode line 300 in electrical contact with the upper portion of the micro-nanofin LED element 102, 103, 104. The insulating layer 600 prevents electrical contact between the two electrode lines 200, 300 facing vertically, and performs a function of more easily implementing the upper electrode line 300.

In addition, as illustrated in FIG. 2, the color conversion layer 700 in which a blue color conversion layer 711, a green color conversion layer 712, and a red color conversion layer 713 are patterned may be further included on the upper electrode line 300 such that each of the plurality of subpixel sites becomes the subpixel site that independently expresses any one color among blue, green, and red. The blue color conversion layer 711, the green color conversion layer 712, and the red color conversion layer 713 may be known color conversion layers that convert light passing through the color conversion layer to take on blue, green, and red colors, in consideration of the wavelength of the light emitted by the provided micro-nanofin LED element 102, 103, 104, and thus the present invention is not particularly limited thereto. On the other hand, when the micro-nanofin LED element 102, 103, 104 is an element that emits blue light, the blue color conversion layer 711 is unnecessary, so the color conversion layer 700 may include the green color conversion layer and the red color conversion layer.

In addition, a protective layer 800 for protecting the above-described color conversion layer 700 may be further provided, and a protective layer used in a typical display in which the color conversion layer 700 is provided may be appropriately employed as the protective layer 800, so the present invention is not particularly limited thereto.

The full-color display according to the first embodiment of the present invention described above may be manufactured by including the steps of (1) self-aligning to include at least two micro-nanopin LED elements which emit substantially the same color of light for each of a plurality of sub-pixel sites formed on a lower electrode line including a plurality of electrodes which are spaced apart in a horizontal direction at a predetermined interval, and have an element length greater than a thickness, wherein a first conductive semiconductor layer, a photoactive layer and a second conductive semiconductor layer are stacked in a thickness direction, (2) forming an upper electrode line so as to be in contact with upper portions of the self-aligned micro-nanofin LED elements, and (3) patterning a color conversion layer on the upper electrode line so that each of the plurality of subpixel sites becomes the subpixel site expressing any one color among blue, green, and red.

First, as step (1), the step of self-aligning to include at least two micro-nanopin LED elements which emit substantially the same color of light for each of a plurality of sub-pixel sites formed on a lower electrode line including a plurality of electrodes which are spaced apart in a horizontal direction at a predetermined interval is performed. Here, the micro-nanofin LED elements have the length greater than the thickness, and the first conductive semiconductor layer, the photoactive layer, and the second conductive semiconductor layer are stacked in a thickness direction in the LED elements.

According to an embodiment of the present invention, step (1) may be performed by including the steps of 1-1) preparing the lower electrode line including the plurality of electrodes spaced apart in the horizontal direction at the predetermined interval, 1-2) injecting a solution including a plurality of the micro-nanofin LED elements which emits substantially the same color of light and has the length greater than the thickness, and in which the first conductive semiconductor layer, the photoactive layer, and the second conductive semiconductor layer are stacked in the thickness direction into the plurality of subpixel sites formed on the lower electrode line; and 1-3) self-aligning the plurality of micro-nanofin LED elements by applying an assembly voltage to the lower electrode line so that the at least two micro-nanofin LED elements contact the different electrodes positioned in each of the subpixel sites on the lower electrode line.

In step 1-2), for example, the solution on ink may be injected using an inkjet. In addition, step 1-3) is the step of self-aligning the plurality of micro-nanofin LED elements using an electric field by applying an assembly voltage. As for the strength, type, etc. of the applied assembly voltage, the entire contents of Korean Patent Application Nos. 10-2013-0080412, 10-2016-0092737, 10-2016-0073572, etc. by the inventor of the present invention may be incorporated herein as reference.

Between steps (1) and (2), the steps of forming the conductive metal layer connecting any one layer of each micro-nanofin LED element contacted the lower electrode line and the lower electrode line and forming the insulating layer on the lower electrode line to a thickness that does not cover the upper surface of the self-aligned micro-nanofin LED element may be further included.

The conductive metal layer may be prepared by patterning a line on which the conductive metal layer is to be deposited by applying a photolithography process using a photosensitive material and then depositing the conductive metal layer or by patterning the deposited metal layer and then etching the patterned metal layer. This process may be performed by appropriately employing a known method, and the content of Korean Patent Application No. 10-2016-0181410 by the inventor of the present invention may be incorporated herein by reference.

After forming the conductive metal layer, the step of forming the insulating layer on the lower electrode line to a thickness that does not cover the upper surface of the self-aligned micro-nanofin LED element may be performed. The insulating layer may be formed through deposition of a known insulating material, for example, an insulating material such as SiO₂ or SiNₓ may be deposited through a PECVD method, an insulating material such as AlN or GaN may be deposited through a MOCVD method, or an insulating material such as Al₂O, HfO₂, ZrO₂ may be deposited through an ALD method. On the other hand, the insulating layer may be formed to a thickness that does not cover the upper surface of the self-aligned micro-nanofin LED element. For this purpose, the insulating layer is formed through deposition to a thickness that does not cover the upper surface or to a thickness that covers the upper surface, and then, dry etching may be performed until the upper surface of the element is exposed.

Next, as step (2), the step of forming the upper electrode line so as to contact the upper portions of the self-aligned micro-nanofin LED elements is performed. The upper electrode line may be implemented by depositing an electrode material after patterning the electrode line using known photolithography or by dry and/or wet etching after depositing the electrode material.

Next, as step (3), the step of patterning the color conversion layer on the upper electrode line is performed so that each of the plurality of subpixel sites becomes the subpixel site expressing any one color of blue, green, and red.

The micro-nanofin LED element provided in the subpixel space can emit blue, white, or UV light colors. In this case, it is the step of providing the color conversion layer capable of converting the light colors emitted for displaying color images into different light colors on the upper portions of the subpixel sites. Preferably, in order to improve color gamut by further increasing color purity, and to improve the front luminous efficiency of the light, for example, green/red, which is color-converted so that the back light in the color conversion layer becomes the front light, a short-wavelength transmission filter is provided on the upper portion of the subpixel sites and the color conversion layer may be formed in one region of the upper portion of the short-wavelength transmission filter.

It is described in the case that the micro-nanofin LED element is a blue LED element. In this case, the short-wavelength transmission filter may be formed on the upper electrode line, and if the plane on which the upper electrode line is formed is not flat, a planarization layer for planarizing the plain on which the upper electrode line is formed is further formed, and then, the short-wavelength transmission filter may be formed on the planarization layer. The short-wavelength transmission filter may be a multilayer film in which thin films of a high refractive index/low refractive index materials are repeated, and the composition of the multilayer film may be [(0.125)SiO₂/(0.25)TiO₂/(0.125)SiO₂]ₘ (m = the number of repeating layers, m is 5 or more) in order to transmit blue and reflect light with a wavelength longer than that of blue. In addition, the thickness of the short-wavelength transmission filter may be 0.5 to 10 µm, but is not limited thereto. The method of forming the short-wavelength transmission filter may be any one of e-beam, sputtering, and atomic layer deposition, but is not limited thereto.

Next, the color conversion layer may be formed on the short-wavelength transmission filter. Specifically, the color conversion layer may be formed by patterning a green color conversion layer on the short-wavelength transmission filter corresponding to some selected subpixel sites among the subpixel sites, and patterning a red color conversion layer on the short-wavelength transmission filter corresponding to some selected subpixel sites among the remaining subpixel sites. The method of forming the patterning may be performed by any one or more methods selected from the group consisting of a screen printing method, photolithography, and dispensing. Meanwhile, the patterning order of the green conversion layer and the red conversion layer is not limited and may be formed simultaneously or in the reverse order. In addition, the red color conversion layer and the green color conversion layer may include a color conversion material of the color conversion layer known in the field of lighting and display, for example, a phosphor that can be excited by a color filter or blue LED element and converted into a desired light color, etc., or a known color conversion material. For example, the green color conversion layer 1930 is a fluorescent layer including a green fluorescent material, and specifically, any one or more phosphors selected from the group consisting of SrGa₂S₄:Eu, (Sr,Ca)₃SiO₅:Eu, (Sr,Ba,Ca)SiO₄:Eu, Li₂SrSiO₄:Eu, Sr₃SiO₄:Ce,Li, β-SiALON:Eu, CaSc₂O₄:Ce, Ca₃Sc₂Si₃O₁₂:Ce, Caα-SiALON:Yb, Caα-SiALON:Eu, Liα-SiALON:Eu, Ta₃Al₅O₁₂:Ce, Sr₂Si₅N₈:Ce, (Ca,Sr,Ba)Si₂O₂N₂:Eu, Ba₃Si₆O₁₂N₂:Eu, γ-AlON:Mn, and γ-AlON:Mn,Mg, but not limited thereto. In addition, the green color conversion layer 1930 is a fluorescent layer including a green quantum dot material, and specifically, any one or more quantum dots selected from the group consisting of CdSe/ZnS, InP/ZnS, InP/GaP/ZnS, InP/ZnSe/ZnS, Peroviskite green nanocrystal, but is not limited thereto.

In addition, the red color conversion layer 1940 is a fluorescent layer including a red fluorescent material, specifically any one or more phosphors selected from the group consisting of (Sr,Ca)AlSiN₃:Eu, CaAlSiN₃:Eu, (Sr,Ca)S:Eu, CaSiN₂:Ce, SrSiN₂:Eu, Ba₂Si₅N₈:Eu, CaS:Eu, CaS:Eu,Ce, SrS:Eu, SrS:Eu,Ce, and Sr₂Si₅N₈:Eu, but not limited thereto.. In addition, the red color conversion layer 1930 is a fluorescent layer including a red quantum dot material, specifically, any one or more quantum dots selected from the group consisting of CdSe / ZnS, InP / ZnS, InP / GaP / ZnS, InP / ZnSe / ZnS, Peroviskite red nanocrystal, but is not limited thereto.

In some subpixel areas, only the short-wavelength transmission filter is disposed on the uppermost layer and the green color conversion layer and the red color conversion layer are not formed on a vertical upper portion, and blue light may be irradiated on this area. On the other hand, green light may be irradiated through the green conversion layer to some subpixel site regions in which the green color conversion layer is formed on the short-wavelength transmission filter. In addition, the remaining subpixel site regions may be irradiated with red light as the red conversion layer is formed on the short-wavelength transmission filter, thereby realizing a color-by-blue LED display.

In addition, preferably, a long-wavelength transmission filter may be further formed on the upper portion including the green and red color conversion layers, and the long-wavelength transmission filter functions as a filter for preventing color purity from being reduced due to mixing of blue light emitted from the element and color-converted green/red lights. The long-wavelength transmission filter may be formed on some or all the green color conversion layer and the red color conversion layer, and preferably only on the green/red color conversion layer. In this case, a multilayer film in which a thin film of a high-refractive/low-refractive materials of reflecting blue, transmitting long-wavelength, and reflecting short-wavelength is repeated may be used as the long-wavelength transmission filter, and the composition of the long-wavelength transmission filter may be [(0.125)TiO₂/(0.25)SiO₂/(0.125)TiO₂]m (m = the number of repeated layers, m is 5 or more). In addition, the thickness of the long-wavelength transmission filter 1950 may be 0.5 to 10 µm, but is not limited thereto. The method of forming the long-wavelength transmission filter may be any one of an electron beam (e-beam), sputtering, and atomic layer deposition method, but is not limited thereto. In addition, in order to form the long-wavelength transmission filter only on the upper portion of the green/red color conversion layer, a metal mask that can expose the green/red color conversion layer and mask the rest is used so that the long-wavelength transmission filter can be formed only in the desired area by using.

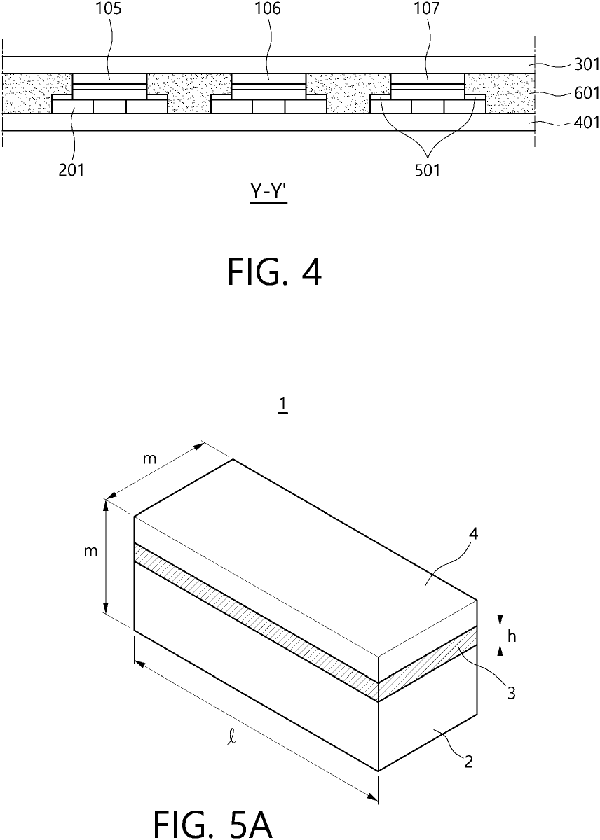

Next, a full-color display according to the second embodiment of the present invention will be described with reference to FIGS. 3 and 4. A full-color LED display 2000 is implemented to include a lower electrode line 201 that includes a plurality of electrodes spaced apart in a horizontal direction at a predetermined interval, a plurality of micro-nanofin LED elements 105, 106, 107 that emits blue, green, or red light independently of each other, and in which at least two elements emitting substantially the same color of light for each of a plurality of subpixel sites S₃,3₄,S₅ are disposed so that the plurality of subpixel sites S₃,3₄,S₅ formed on the lower electrode line 201 independently represents any one color of blue, green, and red, and an upper electrode line 301 disposed to contact upper portions of the plurality of micro-nanofin LED elements 105, 106, 107.

The full-color display 1000 according to the first embodiment described above includes the micro-nanofin LED elements 102, 103, 104 emitting substantially the same color of light. On the other hand, the full-color display 2000 according to the second embodiment is different from the full-color display 1000 in that each of the used micro-nanofin LED elements 105, 106, 107 independently emits blue, green, and red, and at least two elements each independently emitting any one color of blue, green, and red for each of the subpixel sites S₃,S₄,S₅ are disposed. In addition, a separate color conversion layer on the upper electrode line 301 is unnecessary because the element itself disposed in the subpixel sites S₃,S₄,S₅ emits a desired blue, green, or red color. On the other hand, the full-color LED display 2000 according to the second embodiment may further include the conductive metal layer 501 for reducing the resistance of the contact portion between the lower electrode line 201 and the micro-nanofin LED element 105, 106, 107 and, the insulating layer 601 filling between the lower electrode line 201 and the upper electrode line 301.

The full-color LED display 2000 according to the second embodiment described above may be implemented by including the steps of (a) self-aligning to include at least two micro-nanofin LED elements which emit substantially the same color of light for each of a plurality of sub-pixel sites formed on a lower electrode line including a plurality of electrodes which are spaced apart in a horizontal direction at a predetermined interval, wherein the micro-nanofin LED elements include a blue micro-nanofin LED element, a green micro-nanofin LED element so that each of the plurality of subpixel sites becomes the subpixel site expressing any one color among blue, green and red, and have an element length greater than a thickness, wherein a first conductive semiconductor layer, a photoactive layer and a second conductive semiconductor layer are stacked in a thickness direction, and (b) forming an upper electrode line in contact with upper portions of the self-aligned micro-nanofin LED elements.

In addition, step (a) may include the steps of a-1) preparing the lower electrode line including the plurality of electrodes spaced apart in the horizontal direction at the predetermined interval, a-2) injecting a solution including the plurality of the blue micro-nanofin LED elements, the green micro-nanofin LED elements and the red micro-nanofin LED elements having the length greater than the thickness in which the first conductive semiconductor layer, the photoactive layer, and the second conductive semiconductor layer are stacked in the thickness direction into the plurality of subpixel sites formed on the upper electrode line, a-3) self-aligning the plurality of micro-nanofin LED elements by applying an assembly voltage to the lower electrode line so that the at least two micro-nanofin LED elements emitting substantially the same color of light contact the different electrodes positioned in each of the subpixel sites on the lower electrode line. The description of each of these steps is the same as the description of the manufacturing method of the full-color LED display according to the first embodiment described above, so a detailed description will be omitted below.

While the embodiments of the present invention have been described above, the present invention is not limited to the embodiment presented herein. One skilled in the art may easily suggest other embodiments due to addition, modification, deletion, inclusion, and the like of components within the scope and spirit of the present invention, and the addition, modification, deletion, inclusion, and the like of the components fall within the scope and spirit of the present invention.

1-16. (canceled)

17. A method for manufacturing a full-color LED display comprising the steps of:
(1) self-aligning to include at least two micro-nanopin LED elements which emit substantially the same color of light for each of a plurality of sub-pixel sites formed on a lower electrode line including a plurality of electrodes which are spaced apart in a horizontal direction at a predetermined interval, and have an element length greater than a thickness, wherein a first conductive semiconductor layer, a photoactive layer and a second conductive semiconductor layer are stacked in a thickness direction;
(2) forming an upper electrode line to be in contact with upper portions of the self-aligned micro-nanofin LED elements; and
(3) patterning a color conversion layer on the upper electrode line so that each of the plurality of subpixel sites becomes the subpixel site expressing any one color among blue, green, and red.

18. The method according to claim 17, wherein the step (1) includes the steps of:
1-1) preparing the lower electrode line including the plurality of electrodes spaced apart in the horizontal direction at the predetermined interval;
1-2) injecting a solution including a plurality of the micro-nanofin LED elements which emits substantially the same color of light and has the length greater than the thickness, and in which the first conductive semiconductor layer, the photoactive layer, and the second conductive semiconductor layer are stacked in the thickness direction into the plurality of subpixel sites formed on the lower electrode line; and
1-3) self-aligning the plurality of micro-nanofin LED elements by applying an assembly voltage to the lower electrode line so that the at least two micro-nanofin LED elements contact the different electrodes positioned in each of the subpixel sites on the lower electrode line.

19. The method according to claim 17, further comprising, between the steps of self-aligning the micro-nanofin LED elements and forming the upper electrode line, the steps of:
forming a conductive metal layer connecting any one layer of each of the micro-nanofin LED elements in contact with the lower electrode line and the lower electrode line; and
forming an insulating layer on the lower electrode line to a thickness that does not cover upper surfaces of the self-aligned micro-nanofin LED elements.

20. A method for preparing a full-color LED display, comprising the steps of:
(a) self-aligning to include at least two micro-nanofin LED elements which emit substantially the same color of light for each of a plurality of sub-pixel sites formed on a lower electrode line including a plurality of electrodes which are spaced apart in a horizontal direction at a predetermined interval, wherein the micro-nanofin LED elements include a blue micro-nanofin LED element, a green micro-nanofin LED element so that each of the plurality of subpixel sites becomes the subpixel site expressing any one color among blue, green and red, and have an element length greater than a thickness, wherein a first conductive semiconductor layer, a photoactive layer and a second conductive semiconductor layer are stacked in a thickness direction; and
(b) forming an upper electrode line in contact with upper portions of the self-aligned micro-nanofin LED elements.

21. The method according to claim 20, wherein the step (a) includes the steps of:
a-1) preparing the lower electrode line including the plurality of electrodes spaced apart in the horizontal direction at the predetermined interval;
a-2) injecting a solution including each of the plurality of the blue micro-nanofin LED elements, the green micro-nanofin LED elements, and the red micro-nanofin LED elements into the plurality of subpixel sites formed on the lower electrode line, wherein the micro-nanofin LED elements have an element length greater than a thickness, wherein a first conductive semiconductor layer, a photoactive layer and a second conductive semiconductor layer are stacked in a thickness direction; and
a-3) self-aligning the plurality of micro-nanofin LED elements by applying an assembly voltage to the lower electrode line so that the at least two micro-nanofin LED elements emitting substantially the same color of light contact the different electrodes positioned in each of the subpixel sites on the lower electrode line.

22. The method according to claim 20, further comprising, between the steps of self-aligning the micro-nanofin LED elements and forming the upper electrode line, the steps of:
forming a conductive metal layer connecting any one layer of each of the micro-nanofin LED elements in contact with the lower electrode line and the lower electrode line; and
forming an insulating layer on the lower electrode line to a thickness that does not cover upper surfaces of the self-aligned micro-nanofin LED elements.

23. A full-color LED display, comprising:
a lower electrode line that includes a plurality of electrodes spaced apart in a horizontal direction at a predetermined interval;
a plurality of micro-nanofin LED elements that has a length greater than a thickness, in which a first conductive semiconductor layer, a photoactive layer, and a second conductive semiconductor layer are stacked in a thickness direction, and emit substantially the same color of light, in which at least two of the plurality of micro-nanofin LED elements are included for each of a plurality of subpixel sites formed on the lower electrode line;
an upper electrode line disposed to contact upper portions of the plurality of micro-nanofin LED elements; and
a color conversion layer patterned on the upper electrode line so that each of the plurality of subpixel sites becomes the subpixel site expressing any one color among blue, green, and red.

24. The full-color LED display according to claim 23, wherein the light color is blue, white or UV.

25. The full-color LED display according to claim 23, wherein the micro-nanofin LED element is a rod-type element that has a plane having a length and width of nano or micro size, and in which a thickness perpendicular to the plane is smaller than the length.

26. The full-color LED display according to claim 23, further comprising an electrode layer or a polarization inducing layer on the second conductive semiconductor layer of the micro-nanofin LED element, the polarization inducing layer including a first polarization inducing layer formed on one end in a longitudinal direction of the element, and a second polarization inducing layer having an electrical polarity different from that of the first polarization inducing layer on the other end in the longitudinal direction of the element.

27. The full-color LED display according to claim 23, wherein a ratio of the length and thickness of the micro-nanofin LED element is 3: 1 or more.

28. The full-color LED display according to claim 23, wherein a protrusion having a predetermined width and thickness is formed on a lower surface of the first conductive semiconductor layer of the micro-nanofin LED element in a longitudinal direction of the element.

29. The full-color LED display according to claim 23, wherein the micro-nanofin LED element has the length of 1000 to 10000 nm and the thickness of 100 to 3000 nm.

30. The full-color LED display according to claim 23, wherein a lower surface of the first conductive semiconductor layer of the micro-nanofin LED element includes a protrusion having a predetermined width and thickness formed in a longitudinal direction of the element, a width of the protrusion is formed to be 50% or less compared to a width of the micro-nanofin LED element.

31. The full-color LED display according to claim 23, wherein an emission area of the micro-nanofin LED element exceeds twice an area of a vertical cross-section of the micro-nanofin LED element.

32. The full-color LED display according to claim 23, wherein the subpixel site has a unit area of 100 µm×100 µm or less.

33. A full-color LED display, comprising:
a lower electrode line that includes a plurality of electrodes spaced apart in a horizontal direction at a predetermined interval;
a plurality of micro-nanofin LED elements that emits blue, green, or red light independently of each other, has a length greater than a thickness, in which a first conductive semiconductor layer, a photoactive layer, and a second conductive semiconductor layer are stacked in a thickness direction, and in which at least two of the plurality of micro-nanofin LED elements emitting substantially the same color of light for each of a plurality of subpixel sites are disposed so that the plurality of subpixel sites formed on the lower electrode line independently represents any one color of blue, green, and red; and
an upper electrode line disposed to contact upper portions of the plurality of micro-nanofin LED elements.

34. The full-color LED display according to claim 33, wherein the micro-nanofin LED element is a rod-type element that has a plane having a length and width of nano or micro size, and in which a thickness perpendicular to the plane is smaller than the length.

35. The full-color LED display according to claim 33, further comprising an electrode layer or a polarization inducing layer on the second conductive semiconductor layer of the micro-nanofin LED element, the polarization inducing layer including a first polarization inducing layer formed on one end in a longitudinal direction of the element, and a second polarization inducing layer having an electrical polarity different from that of the first polarization inducing layer on the other end in the longitudinal direction of the element.

36. The full-color LED display according to claim 33, wherein a ratio of the length and thickness of the micro-nanofin LED element is 3: 1 or more.

37. The full-color LED display according to claim 33, wherein a protrusion having a predetermined width and thickness is formed on a lower surface of the first conductive semiconductor layer of the micro-nanofin LED element in a longitudinal direction of the element.

38. The full-color LED display according to claim 33, wherein the micro-nanofin LED element has the length of 1000 to 10000 nm and the thickness of 100 to 3000 nm.

39. The full-color LED display according to claim 33, wherein a lower surface of the first conductive semiconductor layer of the micro-nanofin LED element includes a protrusion having a predetermined width and thickness formed in a longitudinal direction of the element, a width of the protrusion is formed to be 50% or less compared to a width of the micro-nanofin LED element.

40. The full-color LED display according to claim 33, wherein an emission area of the micro-nanofin LED element exceeds twice an area of a vertical cross-section of the micro-nanofin LED element.

41. The full-color LED display according to claim 33, wherein the subpixel site has a unit area of 100 µm×100 µm or less.
